(19) United States
(12) Patent Application Publication
(10) Pub. No.: US 2025/0182944 A1
(43) Pub. Date: Jun. 5, 2025

(54) POWER EFFICIENT IRRIGATION CONTROLLERS

(71) Applicant: Rain Bird Corporation, Azusa, CA (US)

(72) Inventor: Harvey J. Nickerson, El Cajon, CA (US)

(21) Appl. No.: 18/970,758

(22) Filed: Dec. 5, 2024

Related U.S. Application Data
(60) Provisional application No. 63/606,541, filed on Dec. 5, 2023.

(51) Int. Cl. H01F 7/06; A01G 25/16; H03K 3/017

(52) U.S. Cl. CPC H01F 7/064; A01G 25/16; H03K 3/017

(57) ABSTRACT

Some embodiments provide an irrigation controller comprising: a signal generator configured to receive a DC voltage and comprising sets of switching elements, wherein one set of the sets of switching elements corresponds to a common line output of the irrigation controller and remaining sets of switching elements correspond to station outputs of the irrigation controller, wherein each set of switching elements is configured to generate an output alternating waveform signal; and a control circuit configured to: output sets of control signals to the sets of switching elements, each set of control signals drives a respective set of switching elements to control characteristics of a respective output alternating waveform signal to be generated by the respective set of switching elements; and control an application of the output alternating waveform signals to a respective common line output connector and respective station output connectors.

### CROSS-REFERENCE TO RELATED APPLICATIONS

This application claims the benefit of U.S. Provisional Application No. 63/606,541 filed Dec. 5, 2023, entitled POWER EFFICIENT IRRIGATION CONTROLLERS (Attorney Docket No. 8473-158496-US), which is incorporated herein by reference in its entirety.

### TECHNICAL FIELD

This invention relates generally to irrigation control.

### BACKGROUND

Irrigation systems are known to provide irrigation to a landscape. Irrigation systems typically include several devices that require power, such as irrigation controllers and the actuating devices that open and close irrigation valves. Irrigation controllers also control solenoid actuated valves that are at one or locations (e.g., in a valve box) in the field and typically a distance from the irrigation controller. It is typical to run power lines from the irrigation controller to each of the solenoid actuated valves. These power lines are typically buried and extend tens to hundreds of feet in length. Additionally, an irrigation system may include one or more other devices in the field that require power, such as sensors, wireless transceivers, and so on. These other devices typically either need to receive power from a central source or otherwise include battery power.

### BRIEF DESCRIPTION OF DRAWINGS

Disclosed herein are embodiments of systems, apparatuses and methods pertaining to power efficient irrigation controllers and related methods. This description includes drawings, wherein:

FIG. 1 illustrates a block diagram of an example power supply system, in accordance with some embodiments.

FIG. 2 illustrates a simplified block diagram of an example efficient power generation unit, in accordance with some embodiments.

FIG. 3 illustrates example switching elements that may be used to implement one or more sets of switching elements that can power one or more solenoids valves, in accordance with some embodiments.

FIG. 4 illustrates example sets of control signals applied to sets of switching elements in accordance with some embodiments.

FIG. 5A illustrates an example power drive system powering an example solenoid, in accordance with some embodiments.

FIG. 5B illustrates example sets of square output alternating waveform signals in accordance with some embodiments.

FIG. 5C illustrates example sets of square output alternating waveform signals with an adjusted duty cycle in accordance with some embodiments.

FIG. 6A illustrates example sets of switching elements powering a solenoid valve in accordance with some embodiments.

FIG. 6B illustrates example sets of control signals and a resulting voltage output alternating sine waveform signal in accordance with some embodiments.

FIG. 7 shows a table of example power efficiency data in accordance with some embodiments.

FIG. 8 illustrates a simplified flow diagram of an example process of controlling irrigation in accordance with some embodiments.

FIG. 9 illustrates an exemplary system for use in implementing methods, techniques, devices, apparatuses, systems, servers, sources and providing power and/or power control, in accordance with some embodiments.

FIGS. 10A and 10B illustrate example output alternating waveform signals to open a non-latching solenoid and then hold the non-latching solenoid open in accordance with some embodiments.

Elements in the figures are illustrated for simplicity and clarity and have not necessarily been drawn to scale. For example, the dimensions and/or relative positioning of some of the elements in the figures may be exaggerated relative to other elements to help to improve understanding of various embodiments. Also, common but well-understood elements that are useful or necessary in a commercially feasible embodiment are often not depicted in order to facilitate a less obstructed view of these various embodiments. Certain actions and/or steps may be described or depicted in a particular order of occurrence while those skilled in the art will understand that such specificity with respect to sequence is not actually required. The terms and expressions used herein have the ordinary technical meaning as is accorded to such terms and expressions by persons skilled in the technical field as set forth above except where different specific meanings have otherwise been set forth herein.

### DETAILED DESCRIPTION

The following description is not to be taken in a limiting sense but is made merely for the purpose of describing the general principles of exemplary embodiments. The scope of the invention should be determined with reference to the claims. Reference throughout this specification to “one embodiment,” “an embodiment,” “some embodiments”, “an implementation”, “some implementations”, “some applications”, or similar language means that a particular feature, structure, or characteristic described in connection with the embodiment is included in at least one embodiment of the present invention. Thus, appearances of the phrases “in one embodiment,” “in an embodiment,” “in some embodiments”, “in some implementations”, and similar language throughout this specification may, but do not necessarily, all refer to the same embodiment.

Irrigation systems usually include a number of valves electronically controlled by an irrigation controller, each valve controlling the flow of water to one or more sprinklers. In some irrigation systems, there are tens of valves to be controlled by an irrigation controller. A typical non-latching solenoid-actuated valve requires continuous AC power from the irrigation controller to open the valve and maintain the valve in an open state for the duration of watering. The available power from the irrigation controller and/or water pressure can limit how many valves can be controlled by the irrigation controller at the same time. Some historical irrigation controllers are powered using iron-core AC transformers to obtain 50/60 Hz 24 VAC to power non-latching solenoids. Regulations are expected to challenge traditional designs to reduce wasted power.

Generally speaking, pursuant to various embodiments, systems, apparatuses, and methods are provided herein useful to providing power to one or more irrigation system components, such as but not limited to valve solenoids, non-latching solenoids, and other irrigation system components. Some embodiments provide an irrigation controller comprising a signal generator configured to receive a DC voltage and comprising sets of switching elements, wherein one set of the sets of switching elements corresponds to a common line output connector of the irrigation controller and remaining sets of switching elements correspond to station outputs of the irrigation controller, wherein each set of switching elements is configured to generate an output alternating waveform signal based at least on the DC voltage; and a control circuit coupled to the signal generator and configured to: output sets of control signals to the sets of switching elements, each set of control signals drives a respective set of switching elements to control characteristics of a respective output alternating waveform signal to be generated by the respective set of switching elements; and control an application of the output alternating waveform signals to a respective common line output connector and respective station output connectors.

Some embodiments provide processes and methods to control irrigation comprising: receiving, at a signal generator, a DC voltage, wherein the signal generator comprises sets of switching elements, wherein one set of the sets of switching elements corresponds to a common line output of the irrigation controller and remaining sets of switching elements correspond to station outputs of the irrigation controller; outputting, by a control circuit, sets of control signals to the sets of switching elements; generating, by each set of switching elements, a respective output alternating waveform signal based at least on the DC voltage and a respective set of control signals of the sets of control signals, wherein each set of control signals drives the respective set of switching elements, of the sets of switching elements, and controlling characteristics of the respective output alternating waveform signal generated by the respective set of switching elements; and controlling an application of the output alternating waveform signals to a respective common line output connector and respective station output connectors.

Accordingly, in some embodiments, an irrigation controller (e.g., residential controller, commercial controller, a stand-alone controller, field controller operated by a server/computer, which may or may not have a user interface, etc.) may be provided that can improve efficiency and in some applications support green power regulations and reduce wasted power. In some embodiments, a power efficient irrigation controller is provided based on a high-efficiency DC power supply to power the irrigation controller and to provide output power to solenoid-operated valves. In some embodiments, the power efficient irrigation controller can selectively provide or create multiple sine and/or square alternating waveform signals from the DC power and may be referred to as a multi-wave controller.

In some embodiments, a power efficient irrigation controller design can use readily available low-cost switching power supplies to generate DC power (e.g., 24 VDC) from AC mains power. In some embodiments, the irrigation controller can operate with a universal AC input 90-250vac 50/60 Hz. This may eliminate the need for expensive iron/copper AC transformers. In some embodiments, a power efficient irrigation controller may comprise and/or use H-bridge technology (switching elements) to generate multiple waveforms (e.g., various 24 VAC waveforms) to power solenoids (e.g., to actuate and/or hold solenoids). In some embodiments, H-bridge technology may be used to generate a square wave to power solenoids. H-bridge technology may be used to generate a sine wave to power solenoids. In some embodiments, H-bridge technology may be used to generate a stepped sine wave to power solenoids. A power generation unit may be external to an irrigation controller, while in some embodiments a power generation unit is internal to an irrigation controller. Generally, the power generation unit can be a power efficient generation unit, and in combination with an irrigation controller can create a power efficient irrigation controller that can control irrigation according to a power efficient irrigation method.

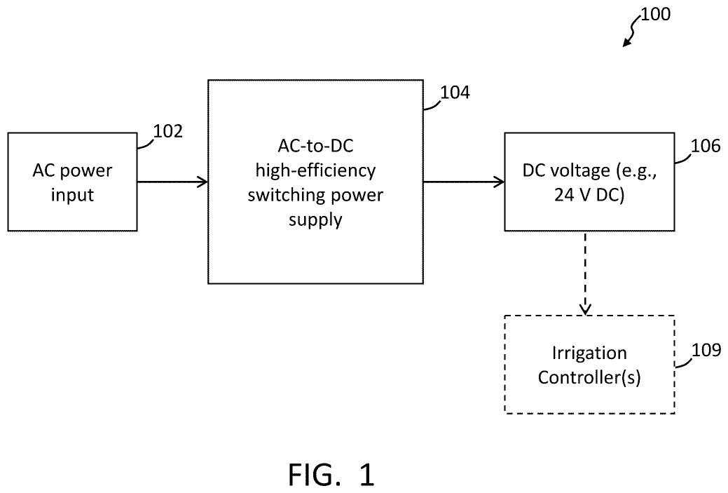

FIG. 1 illustrates a block diagram of an example power supply system 100 that can be utilized with one or more irrigation controllers 109, in accordance with some embodiments. An AC to DC converter 104 can be coupled to one or more input AC signals 102 and configured to convert the input AC signal 102 into one or more DC voltages 106. The DC voltage 106 can be supplied to one or more irrigation controllers 109 and/or other irrigation and/or non-irrigation components. The input AC signal 102 may be any suitable source, such as a 110V or 220V electrical outlet providing an alternating current with which the AC to DC voltage converter 104 can be connected. In some embodiments, the AC to DC voltage converter 104 is an AC-to-DC high efficiency switching power supply that receives an AC power input (the input AC signal 102) and outputs the DC voltage 106, such as 24 VDC, 36 VDC, 48 VDC or other relevant output. In some embodiments, the AC to DC voltage converters 104 and/or alternate suitable switching power supplies are implemented through commercially available devices that are known in the art. In some embodiments, such as for irrigation controllers configured to be installed indoors, the AC to DC voltage converters 104 may a “wall-wart” style supply that plugs into a typical power outlet. In some embodiments, such as for irrigation controllers configured to be installed outdoors, the AC to DC voltage converter 104 may be on-board/integrated with the irrigation controller.

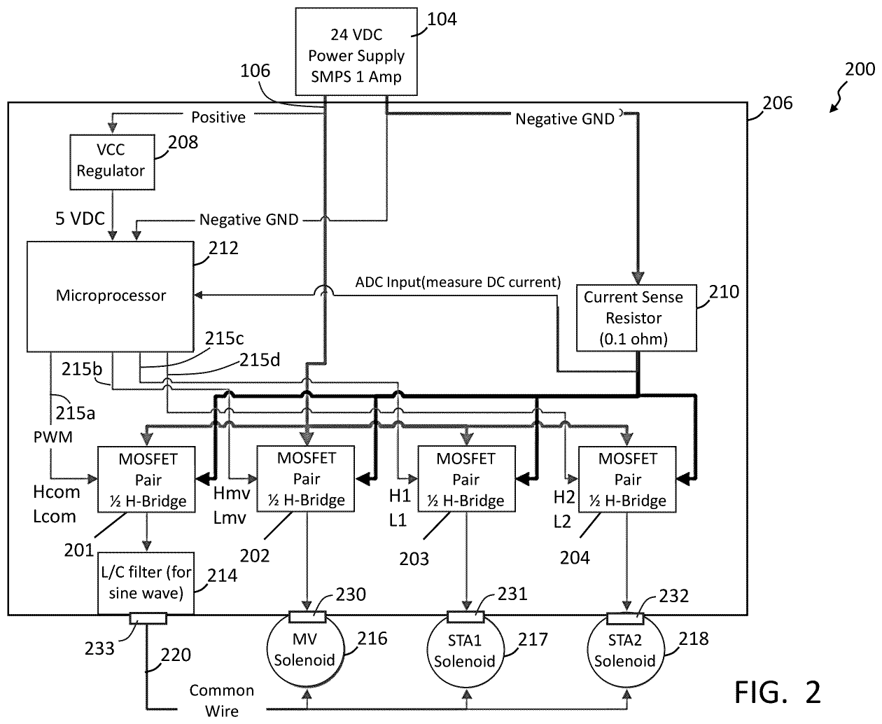

FIG. 2 illustrates a simplified block diagram of an example irrigation control power generation unit 200 according to some embodiments. The power generation unit 200 may be incorporated into an irrigation controller and/or cooperate with an irrigation controller. In some embodiments, the power generation unit 200 may include one or more signal generators 206, one or more control circuits 212, one or more VCC regulators 208, one or more current measure circuits 210, one or more L/C filters 214, and sets of switching elements 201-204. The power generation unit 200 can couple to receive the DC voltage 106 (which may be, for example, a 24 VDC output by the AC to DC voltage converter 104, which may be external to the power generation unit 200 and/or an irrigation controller, or partially or fully incorporated into one of signal generator or irrigation controller) as an input to the signal generator 206. In some embodiments, the AC to DC voltage converter 104 is coupled to the power generation unit 200, while in other embodiments the AC to DC voltage converter 104 may be internal to the power generation unit 200. In some embodiments, the signal generator 206 can include the VCC regulator 208, the current measure circuit 210, and/or the L/C filter 214. In some embodiments, the control circuit 212, the VCC regulator 208, the L/C filter 214, and/or the current measure circuit 210 are externally coupled to the signal generator 206, while in some implementations any suitable combination of the control circuit 212, the VCC regulator 208, the L/C filter 214, the current measure circuit 210, etc., is internal to the signal generator 206 (as shown in FIG. 2). In some embodiments, the sets of switching elements 201, 202, 203, 204 and the L/C filter 214 are internal to the signal generator 206, and the other components described herein are externally coupled to the signal generator 206. In some embodiments, the signal generator 206 is coupled to the AC to DC voltage converter 104 and is configured to generate one or more output alternating waveform signals using the DC voltage 106 from the AC to DC voltage converter 104. The signal generator 206, in some implementations, can include a power consumption level which corresponds to the power used by the signal generator 206 relative to the available power.

In the embodiments shown in FIG. 2, the positive portion of the DC voltage 106 is coupled to the VCC regulator 208 that provides a DC signal (e.g., 5 VDC) together with the negative portion (GND) to operate the control circuit 212, which may be implemented through one or more microprocessors, one or more processors, one or more ASICs, one or more control logic, one or more other such control circuits, or a combination of two or more of such control circuits and/or systems. The DC voltage 106 may also be provided to each of one or more or a set of switching elements 201-204. One or more of the sets of switching elements 201-204 may comprise MOSFET pairs. In some embodiments, each MOSFET pair can form a half H-bridge. It is noted that in some embodiments, the switching elements are half H-bridges, and it is understood that in some embodiments, other digital switches, transistors, digital transistors, digital elements or switching elements, Class D elements, and/or other switching elements may be used. In some embodiments, the switching elements can comprise switching elements, which may or may not be used for amplification. In some aspects, a set of switching elements includes a MOSFET pair, and/or a half H-bridge circuit. Generally, the signal generator 206 includes at least one switching element, though any suitable number of switching elements may be used.

In some embodiments, one set of the sets of switching elements corresponds to a common line output 220 of an irrigation controller, and remaining sets of switching elements correspond to station outputs of the irrigation controller, wherein each set of switching elements is configured to generate a respective output alternating waveform signal based at least on the DC voltage. For example, a set of one or more of the switching elements 202, 203, 204 may correspond to station output connectors 230, 231, 232 and to the common line output connector 233 of the irrigation controller, and can be coupled, directly or though one or more intermediary circuit components, to one or more respective valve solenoid, such as a non-latching solenoid valves 216, 217, 218, pump driver systems, and/or other such irrigation devices. The switching elements, in some embodiments, can be configured to output a respective output alternating waveform signal to one or more of the respective non-latching solenoid valves 216, 217, 218. One or more or each of the sets of switching elements 202, 203, 204 can be configured to output a unique output alternating waveform signal to the respective non-latching solenoid valve 216, 217, 218. The output of each of the solenoid driving sets of switching elements 202, 203 and 204 can be coupled to one or more non-latching solenoid valves 216, 217, and 218 respectively such that each output alternating waveform signal controls an operation of the respective one or more non-latching solenoid valves. Generally, each solenoid valve 216-218 may be included as part of and/or configured to control a station that is fluidly coupled with a water source and may include a set of one or more irrigation devices (e.g., sprinklers, driplines, rotors, etc.) corresponding to a particular solenoid valve and/or station.

In some embodiments, as shown in the example system of FIG. 2, a first set of switching elements 202 may be coupled to a master valve (MV) solenoid valve 216, a second set of switching elements 203 may be coupled to a second non-latching solenoid valve 217 for a first station, and a third set of switching elements 204 may be coupled to a third non-latching solenoid valve 218 for a second station. It is understood that fewer or additional switching elements may be provided for connection to fewer and/or additional solenoid valves and/or stations. In some embodiments, a common line signal along a common wire 220 may be provided by a set of one or more common line switching elements 201 together with the signals output from one or more of sets of switching elements 202, 203, 204 to provide an output signal waveform to one or more or each of the non-latching solenoid valves 216, 217, 218. In some embodiments, the solenoid valves 216-218 can include a master valve (MV) solenoid valve (which may be the solenoid valve 216 shown), and one or more additional station solenoid valves (such as non-latching solenoid valves 217, 218) may be downstream of the master valve solenoid valve. Generally, the master valve solenoid valve is controlled to transition between a closed state and an actuated open state to enable fluid flow downstream to the additional solenoid valves downstream of the master valve solenoid valve to receive a fluid flow.

Generally, the alternating waveform signals output by the sets of switching elements 201, 202, 203, 204 depend on one or more sets of control signals output on control signaling outputs 215a, 215b, 215c, 215d from the control circuit 212. The control circuit 212 may, in some embodiments, include one or more microcontrollers, one or more computers, one or more processor-based device with a processor, memory, and programmable input/output peripherals, which is generally designed to govern the operation of other components and devices. The control circuit 212 may further include and/or be communicatively coupled with common accompanying accessory devices, including but not limited to one or more external memory, one or more transceivers enabling communication with other components and devices, one or more user interfaces (e.g., display, buttons, lights, touchscreen, trackball, etc.), and/or other such accessory devices. These architectural options are well known and understood in the art and require no further description here. The control circuit 212 may be configured (for example, by using corresponding programming stored in a memory as will be well understood by those skilled in the art, which may include programming directly through a user interface and/or via a remote user interface via a wired and/or wireless communication through one or more computer and/or communication networks (e.g., LAN, WAN, Internet, cellular, Wi-Fi, Bluetooth, LoRa, LoRa-WAN, other IEEE 802.11 communications protocol networks, or a combination of two or more of such networks)) to conduct one or more of the steps, actions, and/or functions described herein.

In some embodiments, the control circuit 212 is configured to output sets of control signals to drive at least one switching element (e.g., sets of switching elements 201, 202, 203, 204) to control generation of respective output alternating waveform signals to the station output connectors 230-232 and the common line output connector 233, and/or other output connections. The control circuit 212 may further control, via the control signals, characteristics (e.g., a power level, frequency, duty cycle, shape, etc.) of the alternating waveform signals to actuate at least one solenoid valve (e.g., non-latching solenoid valves 216, 217, 218), in some implementations to maintain the solenoid valve(s) in an open state after actuation, and/or to close the solenoid valve. Specifically, for example, the control circuit 212 may control an application of the output alternating waveform signal to one or more station output connectors 230-232. In some embodiments, the control circuit 212 is configured to output at least a minimum actuation power level for actuating a non-latching solenoid valve and/or to output at least a minimum maintenance or hold power level for maintaining the non-latching solenoid valve in an open state after actuation. Generally, the power consumption level of the DC voltage 106 may be controlled based on the control of the control signals to provide a reduced or a minimum power consumption level when the minimum actuation power level and/or the minimum maintenance power level are used to actuate and maintain the solenoid valve and/or non-latching solenoid, respectively. Generally, a non-latching solenoid valve is configured to open when at least the minimum actuation power level is received, and with some non-latching solenoid valves are configured to remain in the open state when at least the minimum maintenance power level is received. Alternatively, some solenoid valves may be a latching solenoid valve that latches in an open state upon activation without further minimum maintenance power.

In some embodiments, one set of one or more switching elements 201 of the sets of switching elements corresponds to a common line output and couples with a common line output connector 233 of the irrigation controller operating as a common line set of switching elements 201 that can be configured to output a set of one or more common alternating waveform signals along the common wire 220. Generally, the common wire 220 is connected to any combination (though usually each) of the solenoid valves 216, 217, 218. In some embodiments, the control signals output from the control circuit 212 to the common line switching element 201 may include a set of control signals, including a pair of control signals generally referred to below as a high common signal (Hcom) and a low common signal (Lcom). In some embodiments, the control signals output from the control circuit 212 to each of the remaining sets of switching elements 202, 203, 204 may include a set of control signals, including a pair of signals labeled as Hx and Lx (e.g., high master valve signal (Hmv), low master valve signal (Lmv), high 1 signal (H1), low 1 signal (L1), high 2 signal (H2), low 2 signal (L2), etc.). Depending on the sets of control signals and the timing thereof, the resulting output of the sets of switching elements 202, 203, 204 may be any combination of no output waves, sine wave signals, stepped sine wave signals, square wave signals, alternately shaped wave signals, or a combination of wave shape signals, for example. The control circuit is configured to control an application of the output alternating waveform signals to a respective common line output and respective station output connectors. In some embodiments, the generated waveforms may be changed or adjusted during use and/or over time. For example, the control signals may be varied to alter one or more of the shape, amplitude, period (frequency), duty cycle, and/or other characteristics of the output alternating wave form signals or a combination of two or more of such characteristics.

In some embodiments, the signal generator 206 can include a filter circuit 214 at an output of one or more or each of the sets of switching elements to filter one or more of the output alternating waveform signals, such as when a waveform signal comprises a sine wave signal. Such a filter circuit 214 may optionally be implemented, such as in the event the common line switching element 201 is intended to generate one or more sine wave alternating waveform signals, as an L/C filter 214 coupled at the output of the common line set of switching elements 201 and can be configured to smooth the waveform and/or remove high frequency components. Generally, the L/C filter 214 can be coupled to at least one switching element and configured to remove a high frequency component from the output alternating signal (e.g., when the output AC signal is a sine wave signal). In some embodiments, in the event the common line set of switching elements 201 is intended to generate a square wave signal, the L/C filter circuit 214 at the output of the common line set of switching elements 201 may provide no effect and/or be bypassed.

In some embodiments, the signal generator 200 can include a feedback system comprising one or more measure circuits, which may comprise a current measure circuit 210 (e.g., which may, for example, include one or more current sense resistors having a relatively low cumulative impedance dependent on an intended implementation, such as but not limited to 0.1 ohm (1 A→0.1 V)) that can be located for example between a negative portion of the AC to DC voltage converter 104 and one or more or each of the sets of switching elements 201, 202, 203, 204. The current measure circuit 210 provides a measured current when a given set of switching elements 201, 202, 203, 204 is active and provides an output, and/or is inactive and not providing an output. The control circuit 212 can couple with the measure circuit 210 and/or an output of the current measure circuit and can use a current sense signal (ADC Input) output by the current measure circuit 210 to measure DC current in the power generation unit 200 to, at least in part, verify there are no shorts and/or potentially other electrical faults in the system. In some embodiments, the current measure circuit 210 is configured to provide a feedback measured current corresponding to the DC voltage. In some embodiments, the control circuit 212 may be configured to determine the power consumption level of the signal generator 206 based on the measure of the current proportional to the DC voltage.

In some embodiments, the control circuit 212 is configured to output the control signals to control and/or drive one or more of the sets of switching elements 201, 202, 203, 204 to provide the intended alternating waveform signals. Generally, in some embodiments, an approach may be used that is similar to that described in U.S. Pat. No. 11,357,181, granted Jun. 14, 2022, titled DATA MODULATED SIGNAL GENERATION IN A MULTI-WIRE IRRIGATION CONTROL SYSTEM (Docket No. 8473-150383-US), and which is incorporated herein by reference in its entirety. In some embodiments, the output alternating waveform signal may be created by outputting a set of one or more pulse-width modulation (PWM) control signals. Such approaches can result in output waveform signals having any intended shape (e.g., sine wave, stepped sine wave, square wave, etc.), amplitude, duty cycle, frequency and/or other such intended characteristics. In some embodiments, the PWM control signals are applied from the control circuit 212 to the common line set of switching elements 201.

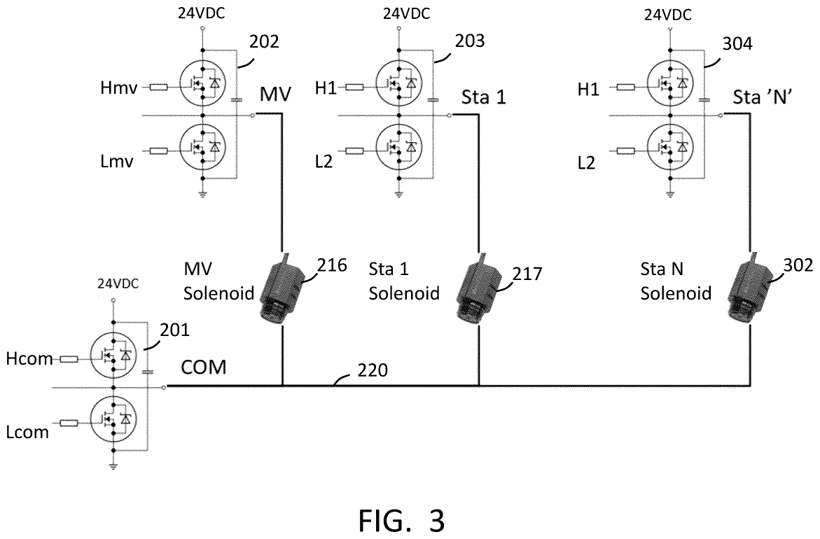

FIG. 3 illustrates example sets of switching elements that may be used to implement one or more of the sets of switching elements 201, 202, 203, 304 (half H-bridges) that can power one or more solenoids valves (e.g., master valve (MV) non-latching solenoid valve 216, station 1 (Sta 1) non-latching solenoid valve 217, station N (Sta N) non-latching solenoid valve 302, etc.) in accordance with some embodiments. The sets of switching elements 304 and the station N solenoid valve 302 may be representative of any integer N number of stations, and subsequently the same integer N number of sets of switching elements and solenoid valves in the power generation unit 200.

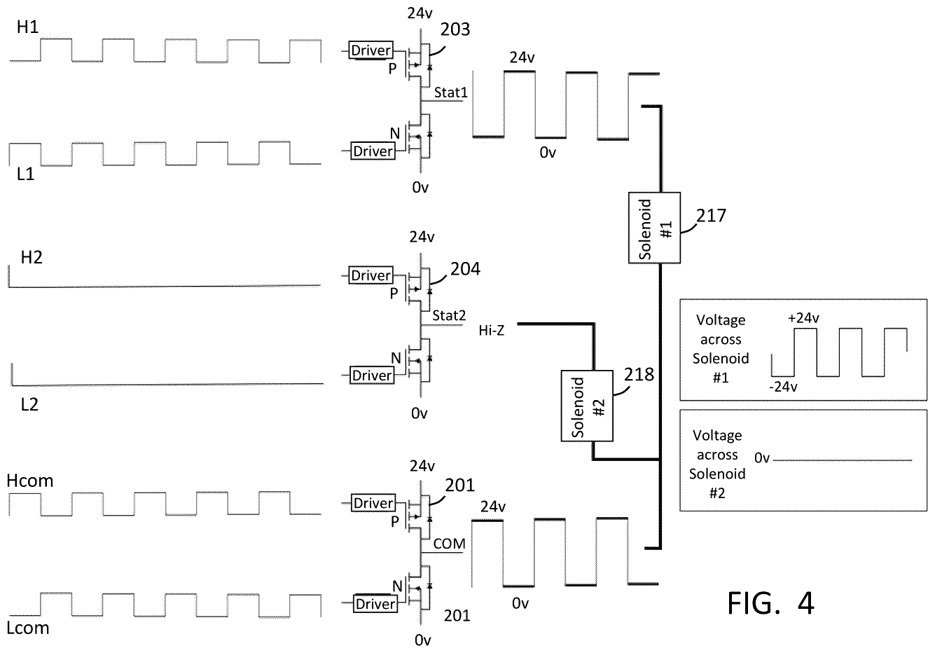

FIG. 4 illustrates example sets of control signals (e.g., H1, L1, H2, L2, Hcom, Lcom) applied to the various sets of switching elements 201, 203, 204 in accordance with some embodiments. For example, the sets of control signals are provided by the control circuit 212 and include DC pulse signals (e.g., alternating between 0 and 5 VDC (set H1, L1 and Hcom, Lcom), or 0 VDC signals (H2, L2). For example, in some embodiments as illustrated in FIG. 4, the control signals of a given set of control signals are out of phase with respect to each other (e.g., 180° out of phase). For example in some embodiments, when: (1) the low control signal L1 (drive output alternating waveform signal) for Station 1 (Sta 1) is 180° out of phase (or phase shifted or phase inverted) from the high control signal H1 (drive output alternating waveform signal) of Station 1; and (2) the high control signal Hcom (output alternating waveform signal) and low control signal Lcom (output alternating waveform signal) of common wire (COM) are, respectively, 180° out of phase with each other and with the high control signal H1 and the low control signal (L1) of Station 1; then (3) the output waveform signal across the station 1 solenoid valve 217 may be a 24 Volt alternating square waveform signal (e.g., from −24V to +24V). Further in some embodiments, when an impedance of the switching element 204 is set high (i.e., the pair of control signals H2 and L2 are 0 volts), there may be no voltage waveform across the station 2 solenoid valve 218 despite the alternating output signal from the common wire (COM) 220 at the common line set of switching elements 201. The sets of control signals H1, L1, H2, L2, Hcom, Lcom (e.g., alternating waveform signals) may be generated based on the control circuit 212.

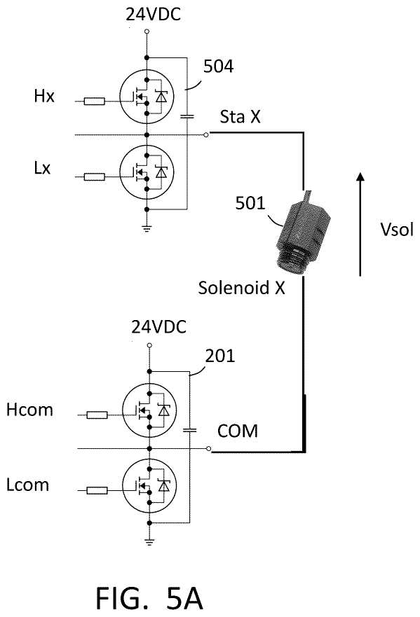

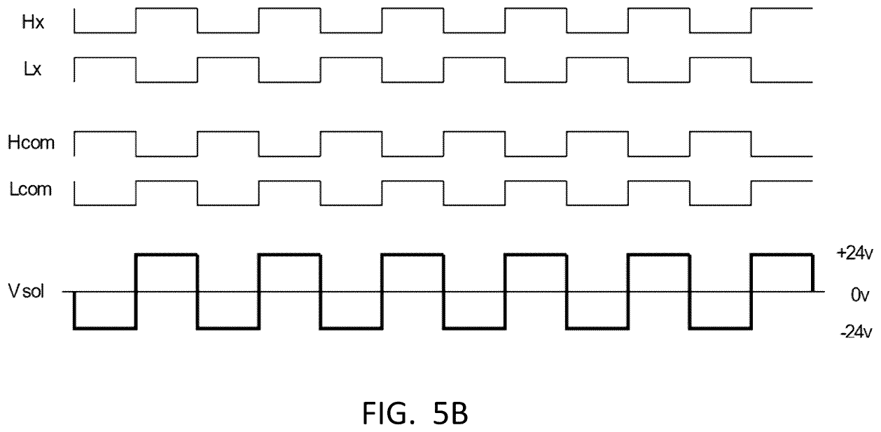

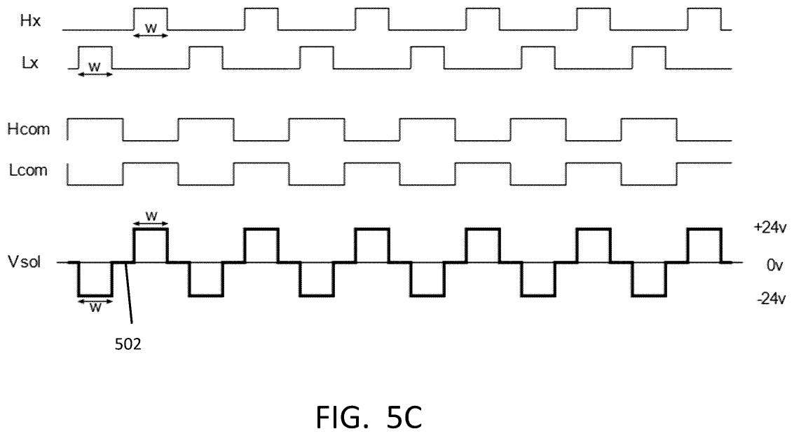

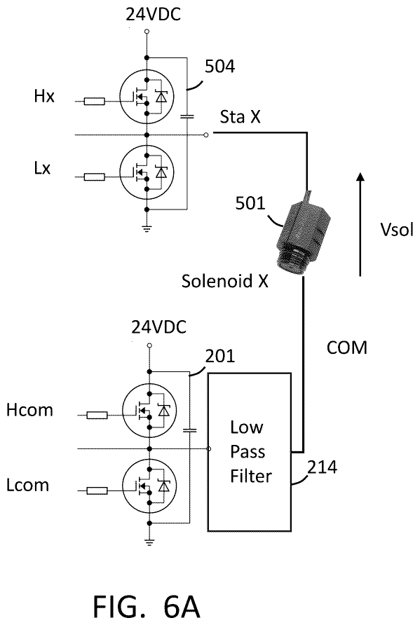

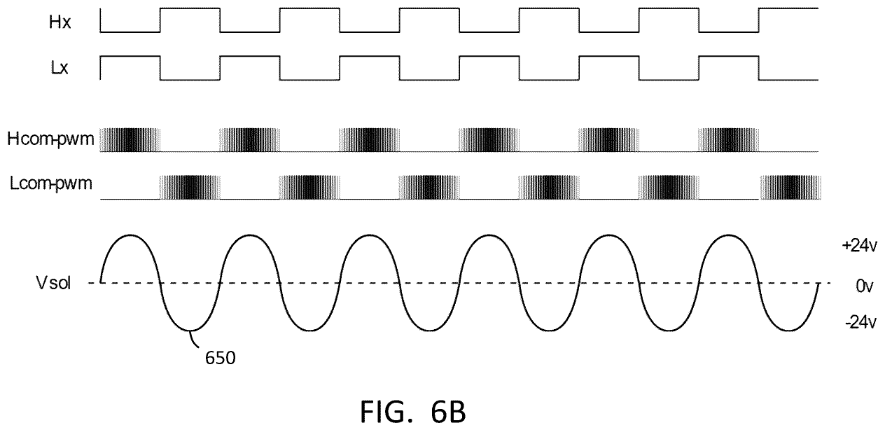

Further examples are shown in the embodiments of FIGS. 5A-5C and 6A-6B. FIG. 5A shows an example power drive system 500 powering a example solenoid valve (solenoid X) 501 (where X may be any integer number, and in some instances may be the same as N), for example using square output alternating waveform signals in accordance with some embodiments. FIG. 5B illustrates example sets of square output alternating waveform signals, which may be applied in the example power drive system 500 of FIG. 5A, in accordance with some embodiments. FIG. 5C illustrate example sets of square output alternating waveform signals, which may be applied in the example power drive system 500 of FIG. 5A, with an adjusted duty cycle in accordance with some embodiments. The control circuit, in some embodiments, can be configured to alter a duty cycle of one or more control signals of a set of control signals to alter a power level of one or more output alternating waveform signals. In some implementations, the power level to the one or more solenoid valves (e.g., non-latching solenoid valves) may be adjustable by adjusting a duty cycle of one or more of the control signals, and the control circuit 212 may be configured to control the duty cycle of the one or more control signals. Adjusting the duty cycle of the control signals can, in some embodiments, directly affect a deadtime window 502 of the output waveform signal Vsol (see FIG. 5C). Generally, the voltage waveform Vsol across a solenoid valve X 501 depends on the sets of control (drive) signals Hx, Lx, and Hcom, Lcom of the sets of switching elements 504 and 201, respectively. As shown in the example of FIG. 5B, an example square output alternating waveform signal can output across the solenoid valve X 501. Further, as shown in the example of FIG. 5C, by controlling/adjusting a duty cycle (w) of one or more of the sets of control signals Hx, Lx, the power of the waveform signal Vsol to the solenoid valve X 501 can be adjusted (e.g., from 0-100%). In some embodiments, a shorter duty cycle creates a larger deadtime window 502, and the larger deadtime window 502 typically applies a lower power level to a respective solenoid valve. In some implementations, shortening the duty cycle w can provide a longer duration deadtime window 502. The longer the deadtime window 502, in some implementations, the less power is applied to the solenoid valve X 501. In some embodiments, a longer duty cycle creates a smaller deadtime window 502, and the smaller deadtime window 502 applies a higher power level to a respective solenoid valve. Reducing or minimizing the deadtime window 502 can increase or maximize the power to the solenoid valve X 501 (such as shown in FIG. 5B, although for simplicity no deadtime window is shown). Similar to that shown in FIG. 4, in some embodiments, the sets of control signals Hx, Lx and Hcom, Lcom provided by the control circuit 212 are DC pulse signals (e.g., alternating between 0 and 5 VDC). Further, in some embodiments, the control signals of a given set of control signals are out of phase with respect to each other (e.g., Lx is 180° out of phase from Hx, and Lcom is 180° out of phase from Hcom), and the control signals of the sets of control signals are out of phase with respect to each other (e.g., Hcom is 180° out of phase from Hx, and Lcom is 180° out of phase from Lx).

The control circuit, in some embodiments, can adjust the output control signals to control one or more of the switching elements causing an adjustment to a duty cycle of the control signals applied to the one or more switching elements. The adjustment in duty cycle can cause a variation in a deadtime window applied to the one or more switching elements that causes a corresponding adjust to one or more output alternating waveform signals as a function of the deadtime window and/or ratio of a duration of the deadtime window relative to the duty cycle. For example, in some embodiments, to control buzzing noises of solenoids, the size of the deadtime window 502 may be increased by adjusting duty cycle (w) as shown in FIG. 5C. And as shown, in the illustrated embodiments of FIGS. 5B and 5C, the set of output alternating waveform signals across solenoid valve X 501 are square waveform signals.

Modulation of the duty cycle w and/or deadtime window 502 can, in some embodiments, provide for the output alternating waveform signals resulting in a high initial power waveform to a non-latching solenoid (e.g., to actuate the solenoid to transition to an open state), then after a period of time corresponding to actuation of the valve, changing a set of one or more control signals to the corresponding one or more sets of switching elements to provide a set of one or more adjusted alternating waveform signals to change to a lower power waveform across the non-latching solenoid (e.g., to maintain or hold the non-latching solenoid in the open state). It is noted that in some embodiments, the setting and/or changing of the control signals Hx and Lx can be on a per station basis, enabling independent control of different stations.

FIG. 6A illustrates example sets of switching elements 201, 504 powering a solenoid valve X 501 (e.g., a non-latching solenoid), for example using a resulting output alternating sine waveform signal, in accordance with some embodiments. FIG. 6B illustrates example sets of control signals and a resulting sine output alternating waveform signal 650 (Vsol) across the solenoid valve X 501, of FIG. 6A, according to the sets of control signals Hx, Lx and Hcom (e.g., Hcom-pwm), Lcom (e.g., Lcom-pwm). In these embodiments, the set of control signals Hcom, Lcom are each pulse width modulated (PWM) signals. FIG. 6A additionally includes the L/C filter 214 to, at least in part, smooth the output alternating waveform signal 650, and in some implementations, filter out high frequency components in the output alternating waveform signal across the solenoid. In some embodiments, the L/C filter 214 is a low pass filter. While not deadtime window 502 is illustrated in FIG. 6B, similarly to that shown in FIGS. 5A-5C, a duty cycle/deadtime window 502 may be adjusted one or more times to at least in part adjust power supplied to the solenoid valve X 501, and such adjustments may be on a per station basis. Similar to that shown in FIGS. 4 and 5, in some embodiments, the set of control signals Hx, Lx provided by the control circuit 212 are DC pulse signals (e.g., alternating between 0 and 5 VDC) and the set of control signals Hcom, Lcom provided by the control circuit 212 are PWM signals (e.g., 5 V DC PWM signals). Further, in some embodiments, the control signals of a given set of control signals are out of phase with respect to each other (e.g., Lx is 180° out of phase from Hx, and Lcom is 180° out of phase from Hcom), and the control signals of the sets of control signals are out of phase with respect to each other (e.g., Hcom is 180° out of phase from Hx, and Lcom is 180° out of phase from Lx).

It is also noted that in some embodiments, additional protection circuitry may be utilized. For example, in some embodiments, square waves may provide EMI emissions that could potentially interfere with other devices in the area, and in such cases, circuitry can be provided to suppress EMI to an acceptable level. In some embodiments, switching elements may have a higher sensitivity to lightning compared to TRIACS (an alternate type of AC switch), and in such cases, suppression circuits may be added. It is further noted that in some embodiments, when iron-core AC transformers are not used, there may be a weight reduction of the irrigation controller compared with embodiments which include an iron-core AC transformer.

In some embodiments, a power generation unit 200 can couple with one or more external AC to DC voltage converters 104 and/or include one or more AC to DC converters. The AC to DC converters can, in some implementations, be implemented using an off-the-shelf high-efficiency DC wall-wart switching mode power supply. Some embodiments can provide approximately 30-40% power savings relative to using an iron-core AC transformer. In some embodiments, the power generation unit 200 uses a control circuit 212 and reduces (e.g., minimizes) power consumption when stations are not operating. In some embodiments, the power generation unit 200 generates a set of one or more output alternating waveform signals to power one or more solenoids during irrigation, e.g., an example output alternating waveform signal can be a square wave during solenoid turn-on to provide more energy during in-rush. In some embodiments, the square wave is then lowered to a lower power and/or voltage waveform afterwards to reduce energy consumed by the solenoid when holding a non-latching solenoid valve open, and, in some embodiments, the square wave a respective solenoid is not intended to be in an open or actuated state.

An AC to DC voltage converter 104 can operate as a DC power supply providing a DC power (e.g., 24V DC) with a maximum current (e.g., 1 Amp) that can be coupled to a power measuring instrument. It is understood, however, that other ranges of voltages and currents may be used depending on the usage of the DC power supply. The AC to DC voltage converter 104, in some embodiments, can be configured to plug into an electrical outlet (such as a type A and/or a type B outlet) and can be external to the power generation unit 200. In some embodiments, the AC to DC voltage converter 104 may be internal to the power generation unit 200.

In some embodiments, the power generation unit 200 can include the AC to DC voltage converter 104 plugged into an outlet to receive AC voltage. The AC to DC voltage converter 104 can be generally configured to convert the AC voltage into DC voltage 106, and outputs the DC voltage 106 to the power generation unit 200. Generally, in some embodiments, the VCC regulator 208 receives the DC voltage 106 and outputs a consistent voltage. A current measure circuit 210 can receive the negative ground signal of the AC to DC voltage converter 104 and output an ADC signal. One or more of the regulated voltage, the ADC signal, and the negative ground signal of the AC to DC voltage converter 104 can, in some embodiments, be input into the control circuit 212. The control circuit 212 can be configured to provide sets of control signals to one or more sets of switching elements 201, 202, 203, 204. In some embodiments, one or more or each of the sets of switching elements can be connected to the DC voltage 106 on one end and the negative ground portion of the AC to DC voltage converter 104 on the other end. The output of the common line switching element 201 may further be passed through an L/C filter 214 before being provided to the solenoid valves 216, 217, 218 along the common wire 220. The power generation unit 200, in some embodiments, includes a user interface configured to provide information and/or receive inputs from a user. Some or all of the user interface may be physically cooperated with the control circuit, while in other embodiments, some or all of the user interface may additionally or alternatively be implemented remote from the irrigation controller (e.g., via a wired and/or wireless communication), such as through a server, a user mobile device (e.g., smartphone, laptop, etc.), computer, etc. For example, the user interface may enable a user to turn one or more of the stations and/or solenoid valves 216, 217, 218 on and/or off.

The user interface can include buttons, display, lights, LEDs, touchscreen, etc. In some embodiments, the user interface is configured to provide a user with further control of a plurality of additional functions related to the irrigation controller and/or the power generation unit 200 (e.g., period of time on, type of signal output, etc.). In some embodiments, once a solenoid valve has been opened, the power generation unit 200 may lower the output voltage to the respective solenoid valve in order to hold a non-latching solenoid valve in an open state to further reduce power consumption (e.g., less power is typically needed to keep a non-latching solenoid valve open than is needed to initially open the solenoid valve). In some embodiments, an actuation power level is supplied to actuate at least one solenoid valve, and a maintenance power level is supplied to maintain the at least one solenoid valve in an open state after actuation of the at least one solenoid valve. Generally, the actuation power level is greater than the maintenance power level. In some embodiments, the control circuit is configured to output the sets of control signals to result in the generation of output alternating waveform signals having different waveforms from each other.

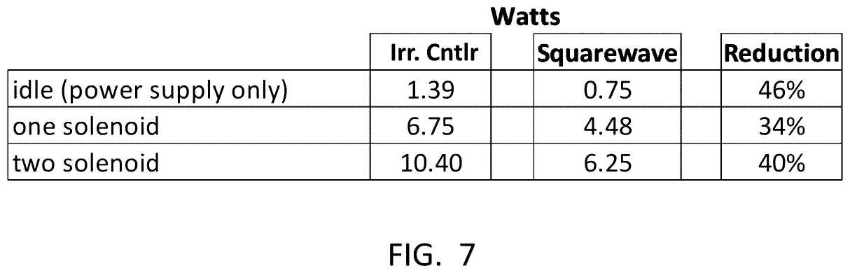

FIG. 7 shows a table of example power savings comparing an off-the-shelf irrigation controller illustrating an efficiency of a power efficient controller and corresponding power generation unit 200 in accordance with some embodiments.

A legacy irrigation controller column, representative of the off-the-shelf legacy irrigation controller, shows the power in watts measured from the off-the-shelf controller and the square wave column includes the power in watts measured with an example irrigation controller and corresponding power generation unit 200 providing a square wave signal to the solenoid. In this case, when the irrigation controller and irrigation controller are idle (i.e., there is no active irrigation or power output from the controllers), there is a 46% reduction in power use with the power efficient irrigation controller and the power generation unit 200. When one solenoid valve is being activated, there is a 34% reduction in power use with the power efficient irrigation controller and power generation unit 200. When two solenoid valves are being activated at the same time, there is a 40% reduction in power use with the power efficient irrigation controller and power generation unit 200. Thus, as can be seen, in some embodiments, a power efficient irrigation controller including a power generation unit 200 such as described herein can provide a reduction in power when idle and also when controlling solenoid valves.

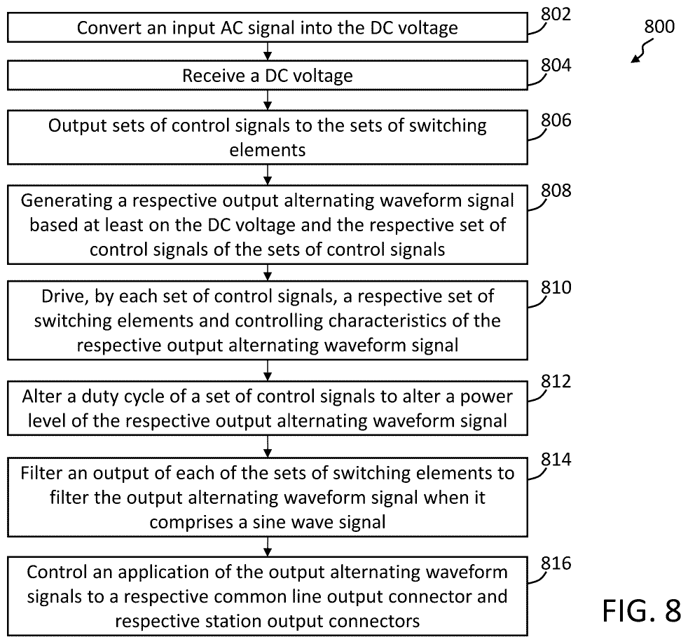

FIG. 8 illustrates a simplified flow diagram of a process 800 of controlling irrigation to provide power to solenoid valves (e.g., non-latching solenoid valves), in accordance with some embodiments. It is generally contemplated that the process 800 may use some or all of the components described above, such as, for example, the power generation unit described above. In some embodiments, the process 800 includes optional step 802 where an input AC signal is converted into a DC voltage. In step 804, a DC voltage, which may be converted in step 802, is received at a signal generator (e.g., signal generator 206). In some embodiments, the signal generator comprises sets of switching elements (e.g., sets of switching elements 201, 202, 203, 204), with at least one set of switching elements of the sets of switching elements (e.g., set of switching elements 201) corresponding to a common line output of an irrigation controller, and remaining sets of switching elements corresponding to one or more station outputs (e.g., set of switching elements 202, 203, 204) of the irrigation controller.

In step 806, sets of control signals can be output by a control circuit (e.g., control circuit 212) to the sets of switching elements (e.g., sets of switching elements 201, 202, 203, 204). In some embodiments, the outputting of the sets of control signals can comprise outputting one or more of the sets of control signals as sets of square wave control signals. Additionally or alternatively, in some embodiments, the outputting of one or more of the sets of control signals can comprises outputting one or more sets of pulse width modulated (PWM) control signals. In step 808, a respective output alternating waveform signal is generated by each set of switching elements based at least on the DC voltage and the respective set of control signals of the sets of control signals. In step 810, each set of control signals can drive a respective set of switching elements (e.g., sets of switching elements 201, 202, 203, 204), of the sets of switching elements, and control characteristics of a respective output alternating waveform signal generated by the respective set of switching elements. In some embodiments, the outputting the sets of control signals can drive the sets of switching elements with one or more or each set of control signals, of the sets of control signals, comprising two control signals that are out of phase with respect to each other (e.g., 180 degrees out of phase, however, other phase differences may be applied). The outputting of the sets of control signals, in some embodiments, can comprises outputting a first set of control signals driving a first set of switching elements corresponding to the given non-latching solenoid and outputting a second set of control signals to a second set of switching elements corresponding to the common line output of the irrigation controller.

In some embodiments, the process 800 includes step 812 where a duty cycle of a set of control signals, of the sets of control signals, can be altered to alter a power level of the respective output alternating waveform signal. In step 814, an output of each of the sets of switching elements is filtered to filter the output alternating waveform signal when it comprises a sine wave signal. In some embodiments, the outputting the sets of control signals can comprise driving the one set of the sets of switching elements that corresponds to the common line output of the irrigation controller and a plurality of the remaining sets of switching elements that correspond to the station outputs of the irrigation controller. In step 816 application of the output alternating waveform signals to a solenoid is controlled, e.g., by the control circuit, and in some implementations the output alternating waveform signal is provided to more than one non-latching solenoid at the same time.

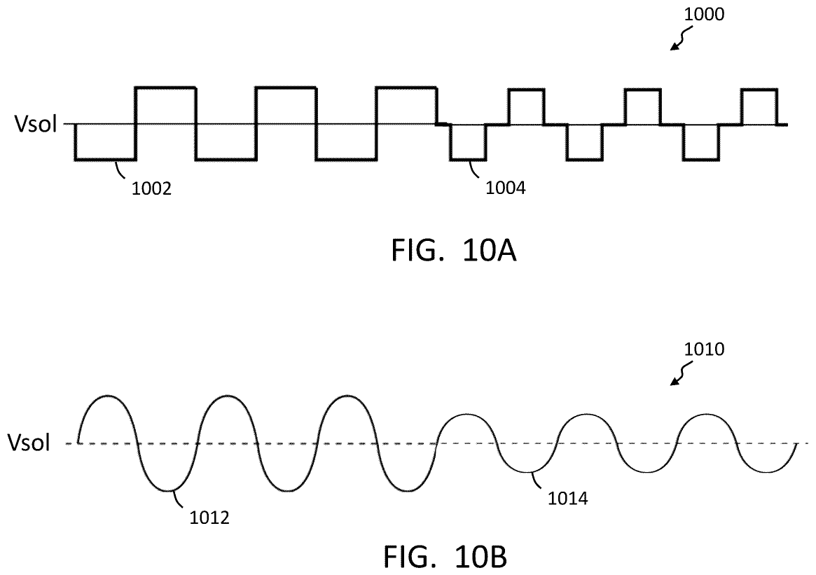

As described above, in some embodiments, an output alternating waveform signal can be provided initially having a first power level sufficient to actuate or move a non-latching solenoid valve from a closed to an open position, and after a period of time to ensure that the valve is open, the output alternating waveform signal is switched to having a second power level lower than the first power level and sufficient to hold or maintain the non-latching solenoid valve in the open position. Referring next to FIGS. 10A and 10B, example output alternating waveform signals are shown in accordance with some embodiments.

Referring first to FIG. 10A, a waveform 1000 has a first stage 1002 of an alternating waveform having the first power level followed by a second stage 1004 of an alternating waveform having the second power level. In the illustrated embodiment, the second stage 1004 starts after 3 cycles of the first stage 1002, but it is understood that the number of cycles and/or timing of the first stage can vary depending on the application, the solenoids being used, length of the station and common lines, and so on. In some embodiments, a time duration of the first stage 1002 of the alternating waveform corresponds to 4 to 10 cycles of the first stage. In some embodiments, the sets of control signals and corresponding sets of switching elements of FIG. 5B are used to generate the first stage 1002, and the sets of control signals and corresponding sets of switching elements of FIG. 5C are used to generate the second stage 1004. As seen, by the control circuit changing the sets of control signals (which can happen cycle by cycle), the shape of the output alternating waveform signal can change to alter the power level of the signal provided to the non-latching solenoid valve. In some embodiments, the waveform 1000 may be referred to as a multi-stage output signal.

Referring next to FIG. 10B, a waveform 1010 has a first stage 1012 of an alternating waveform having the first power level followed by a second stage 1014 of an alternating waveform having the second power level. In the illustrated embodiment, the second stage 1014 starts after 3 cycles of the first stage 1012, but it is understood that the number of cycles and/or timing of the first stage can vary depending on the application, the solenoids being used, length of the station and common lines, and so on. In some embodiments, a time duration of the first stage 1012 of the alternating waveform corresponds to 4 to 10 cycles of the first stage. In some embodiments, the sets of control signals and corresponding sets of switching elements of FIG. 6B are used to generate the first stage 1012 and the second stage 1014, wherein modulation of the pulses of the sets of control signals Hcom-pwm and Lcom-pwm are varied to result in the lower power second stage 1014. As seen, by the control circuit changing the sets of control signals (which can happen cycle by cycle), the shape of the output alternating waveform signal can change to alter the power level of the signal provided to the non-latching solenoid valve. In some embodiments, the waveform 1010 may be referred to as a multi-stage output signal.

APPENDIX A is provided to illustrate the programming of the control circuit 212 in accordance with some embodiments. Appendix A is example source code for the control circuit 212 and provides the settings and instructions for outputting the proper drive signals Hx, Lx, Hcom, Lcom to create a square alternating waveform signal or a sine alternating waveform signal, and when to switch to a lower voltage waveform for holding the valve open. It is understood that this is one example of a process of the control circuit 212, and that other implementations may include few or additional steps and considerations. APPENDIX A is incorporated herein by reference in its entirety.

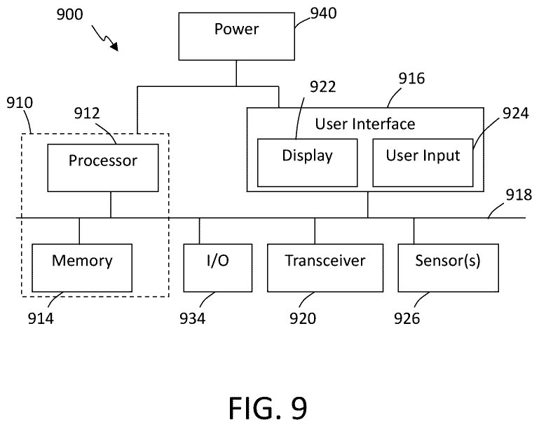

Further, the circuits, circuitry, systems, devices, processes, methods, techniques, functionality, services, servers, sources and the like described herein may be utilized, implemented and/or run on many different types of devices and/or systems. FIG. 9 illustrates an exemplary system 900 that may be used for implementing any of the components, circuits, circuitry, systems, functionality, apparatuses, processes, or devices of the power supply system 100, irrigation controller 109, the signal generator 200, the control circuit 212, and/or other above or below mentioned systems or devices, or parts of such circuits, circuitry, functionality, systems, apparatuses, processes, or devices. However, the use of the system 900 or any portion thereof is certainly not required.

By way of example, the system 900 may comprise one or more control circuits or processor modules 912, one or more memory 914, and one or more communication links, paths, buses or the like 918. Some embodiments may include one or more user interfaces 916, and/or one or more internal and/or external power sources or supplies 940. The control circuit 912 can be implemented through one or more processors, microprocessors, central processing unit, logic, local digital storage, firmware, software, and/or other control hardware and/or software, and may be used to execute or assist in executing the steps of the processes, methods, functionality and techniques described herein, and control various communications, decisions, programs, content, listings, services, interfaces, logging, reporting, etc. Further, in some embodiments, the control circuit 912 can be part of control circuitry and/or a control system 910, which may be implemented through one or more processors with access to one or more memory 914 that can store instructions, code and the like that is implemented by the control circuit and/or processors to implement intended functionality. In some applications, the control circuit and/or memory may be distributed over a communications network (e.g., LAN, WAN, Internet, Wi-Fi, Bluetooth, cellular, etc.) providing distributed and/or redundant processing and functionality. Again, the system 900 may be used to implement one or more of the above or below, or parts of, components, circuits, systems, processes and the like.

The user interface 916 can allow a user to interact with the system 900 and receive information through the system. In some instances, the user interface 916 includes a display 922 and/or one or more user inputs 924, such as buttons, touch screen, track ball, keyboard, mouse, etc., which can be part of or wired or wirelessly coupled with the system 900. Typically, the system 900 further includes one or more communication interfaces, ports, transceivers 920 and the like allowing the system 900 to communicate over a communication bus, a distributed computer and/or communication network (e.g., a local area network (LAN), the Internet, wide area network (WAN), etc.), communication link 918, other networks or communication channels with other devices and/or other such communications or combination of two or more of such communication methods. Further the transceiver 920 can be configured for wired, wireless, optical, fiber optical cable, satellite, or other such communication configurations or combinations of two or more of such communications. Some embodiments include one or more input/output (I/O) ports 934 that allow one or more devices to couple with the system 900. The I/O ports can be substantially any relevant port or combinations of ports, such as but not limited to USB, Ethernet, or other such ports. The I/O interface 934 can be configured to allow wired and/or wireless communication coupling to external components. For example, the I/O interface can provide wired communication and/or wireless communication (e.g., Wi-Fi, Bluetooth, cellular, RF, and/or other such wireless communication), and in some instances may include any known wired and/or wireless interfacing device, circuit and/or connecting device, such as but not limited to one or more transmitters, receivers, transceivers, or combination of two or more of such devices.

In some embodiments, the system may include one or more sensors 926 to provide information to the system and/or sensor information that is communicated to another component. The sensors can include substantially any relevant sensor, such rain sensor, wind sensor, moisture sensor, current sensor, voltage sensor, movement sensor, barcode reader sensors, RFID tag reader sensors, other sensors, or a combination of two or more of such sensors. The foregoing examples are intended to be illustrative and are not intended to convey an exhaustive listing of all possible sensors. Instead, it will be understood that these teachings will accommodate sensing any of a wide variety of circumstances in a given application setting.

The system 900 comprises an example of a control and/or processor-based system with the control circuit 912. Again, the control circuit 912 can be implemented through one or more processors, controllers, central processing units, logic, software and the like. Further, in some implementations the control circuit 912 may provide multiprocessor functionality.

The memory 914, which can be accessed by the control circuit 912, typically includes one or more processor-readable and/or computer-readable media accessed by at least the control circuit 912, and can include volatile and/or nonvolatile media, such as RAM, ROM, EEPROM, flash memory and/or other memory technology. Further, the memory 914 is shown as internal to the control system 910; however, the memory 914 can be internal, external or a combination of internal and external memory. Similarly, some or all of the memory 914 can be internal, external or a combination of internal and external memory of the control circuit 912. The external memory can be substantially any relevant memory such as, but not limited to, solid-state storage devices or drives, hard drive, one or more of universal serial bus (USB) stick or drive, flash memory secure digital (SD) card, other memory cards, and other such memory or combinations of two or more of such memory, and some or all of the memory may be distributed at multiple locations over the computer network. The memory 914 can store code, software, executables, scripts, data, content, lists, programming, programs, log or history data, user information, customer information, product information, and the like. While FIG. 9 illustrates the various components being coupled together via a bus, it is understood that the various components may actually be coupled to the control circuit and/or one or more other components directly.

In some embodiments, the control circuit is further configured to adjust the output control signals over time comprising outputting a first output control signal to produce the output AC signal at a first power level to actuate a first irrigation controller causing the first irrigation controller to transition to an actuated state, and outputting second output control signal to produce the output AC signal at a second power level configured to maintain the first irrigation controller in the actuated state. The control circuit, in adjusting the output control signals, can be further configured to adjust the output control signals to control the at least one switching element causing an adjustment to a duty cycle of at least one control signal of the control signals applied to the at least one switching element varying a deadtime window applied to the at least one switching element causing a corresponding adjust to the output AC signal as a function of the deadtime window. In some embodiments, the first power level is greater than the second power level.

The following patent documents are incorporated in their entirety herein by reference:
U.S. Provisional Patent Application No. 63/605,128 (Attorney docket No. 8473-158529-US) entitled OUTPUT SIGNAL POWER MANAGEMENT FOR IRRIGATION CONTROLLERS, filed on Dec. 1, 2023;
U.S. Non-Provisional patent application Ser. No. 18/966,069 (Attorney docket No. 8473-160760-US) entitled OUTPUT SIGNAL POWER MANAGEMENT FOR IRRIGATION CONTROLLERS, filed on Dec. 2, 2024; and
U.S. Pat. No. 11,357,181, granted Jun. 14, 2022, titled DATA MODULATED SIGNAL GENERATION IN A MULTI-WIRE IRRIGATION CONTROL SYSTEM (Docket No. 8473-150383-US).

Those skilled in the art will recognize that a wide variety of other modifications, alterations, and combinations can also be made with respect to the above described embodiments without departing from the scope of the invention, and that such modifications, alterations, and combinations are to be viewed as being within the ambit of the inventive concept.

1. An irrigation controller comprising:
a signal generator configured to receive a DC voltage and comprising sets of switching elements, wherein one set of the sets of switching elements corresponds to a common line output of the irrigation controller and remaining sets of switching elements correspond to station outputs of the irrigation controller, wherein each set of switching elements is configured to generate an output alternating waveform signal based at least on the DC voltage; and
a control circuit coupled to the signal generator and configured to:
output sets of control signals to the sets of switching elements, each set of control signals drives a respective set of switching elements to control characteristics of a respective output alternating waveform signal to be generated by the respective set of switching elements; and
control an application of the output alternating waveform signals to a respective common line output connector and respective station output connectors.

2. The irrigation controller of claim 1 further comprising an alternating current (AC) to direct current (DC) converter configured to convert an input AC signal into the DC voltage.

3. The irrigation controller of claim 1 wherein the output alternating waveform signals comprise one or more of a square wave signal, a sine wave signal, and a stepped sine wave signal.

4. The irrigation controller of claim 1 wherein the control circuit is configured to alter a duty cycle of a set of control signals to alter a power level of the respective output alternating waveform signal.

5. The irrigation controller of claim 1 further comprises a filter circuit at an output of the one set of the sets of switching elements that corresponds to the common line output of the irrigation controller to filter the output alternating waveform signal when it comprises a sine wave signal.

6. The irrigation controller of claim 1 wherein the control circuit is configured to output the sets of control signals as sets of square wave control signals.

7. The irrigation controller of claim 1 wherein the control circuit is configured to output the sets of control signals as sets of pulse width modulated (PWM) control signals.

8. The irrigation controller of claim 1 wherein the control circuit is configured to output the sets of control signals to drive the sets of switching elements, where each set of control signals, of the sets of control signals, comprises two control signals that are out of phase with respect to each other.

9. The irrigation controller of claim 1 wherein, to provide an output power signal across a given non-latching solenoid, the control circuit is configured to output a first set of control signals to drive a first set of switching elements corresponding to the given non-latching solenoid and output a second set of control signals to a second set of switching elements corresponding to the common line output of the irrigation controller.

10. The irrigation controller of claim 1 wherein the control circuit is configured to output the sets of control signals to drive the one set of the sets of switching elements that corresponds to the common line output of the irrigation controller and a plurality of the remaining sets of switching elements that correspond to the station outputs of the irrigation controller, wherein output power is provided to more than one non-latching solenoid at the same time.

11. The irrigation controller of claim 1 wherein the control circuit is configured to output the sets of control signals to result in the generation of output alternating waveform signals having different waveforms from each other.

12. The irrigation controller of claim 1 wherein the control circuit is configured to output the sets of control signals over time to provide the respective output alternating waveform signal to be generated by the respective set of switching elements, wherein the output alternating waveform signal comprises a multi-stage output signal comprising:
a first stage of an alternating waveform having a first power level sufficient to cause actuation of a non-latching solenoid valve from a closed position to an open position; and
a second stage of the alternating waveform following the first stage and having a second power level that is lower than the first power level and is sufficient to maintain the non-latching solenoid valve in the open position.

13. A method of controlling irrigation comprising:
receiving, at a signal generator, a DC voltage, wherein the signal generator comprises sets of switching elements, wherein one set of the sets of switching elements corresponds to a common line output of an irrigation controller and remaining sets of switching elements correspond to station outputs of the irrigation controller;
outputting, by a control circuit, sets of control signals to the sets of switching elements;
generating, by each set of switching elements, a respective output alternating waveform signal based at least on the DC voltage and a respective set of control signals of the sets of control signals, wherein each set of control signals drives the respective set of switching elements, of the sets of switching elements, and controlling characteristics of the respective output alternating waveform signal generated by the respective set of switching elements; and
controlling an application of the output alternating waveform signals to a respective common line output connector and respective station output connectors.

14. The method of claim 13, further comprising:
converting an input AC signal into the DC voltage.

15. The method of claim 13, wherein the output alternating waveform signals comprise one or more of a square wave signal, a sine wave signal, and a stepped sine wave signal.

16. The method of claim 13, further comprising:
altering a duty cycle of a set of control signals to alter a power level of the respective output alternating waveform signal.

17. The method of claim 13, further comprising:
filtering an output of the one set of the sets of switching elements that corresponds to the common line output of the irrigation controller to filter the output alternating waveform signal when it comprises a sine wave signal.

18. The method of claim 13, wherein the outputting the sets of control signals comprises outputting the sets of control signals as sets of square wave control signals.

19. The method of claim 13, wherein the outputting the sets of control signals comprises outputting sets of pulse width modulated (PWM) control signals.

20. The method of claim 13, wherein the outputting the sets of control signals comprises driving the sets of switching elements, wherein each set of control signals, of the sets of control signals, comprises two control signals that are out of phase with respect to each other.

21. The method of claim 13, wherein the outputting the sets of control signals comprises outputting a first set of control signals driving a first set of switching elements corresponding to the given non-latching solenoid and outputting a second set of control signals to a second set of switching elements corresponding to the common line output of the irrigation controller.

22. The method of claim 13, wherein the outputting the sets of control signals comprises driving the one set of the sets of switching elements that corresponds to the common line output of the irrigation controller and a plurality of the remaining sets of switching elements that correspond to the station outputs of the irrigation controller, and providing output power to more than one non-latching solenoid at the same time.

23. The method of claim 13, wherein the outputting the sets of control signals comprises outputting the sets of control signals resulting in generating output alternating waveform signals having different waveforms from each other.

24. The method of claim 13, wherein the respective output alternating waveform signal generated by the respective set of switching elements comprises a multi-stage output signal comprising:
a first stage of an alternating waveform having a first power level sufficient to cause actuation of a non-latching solenoid valve from a closed position to an open position; and
a second stage of the alternating waveform following the first stage and having a second power level that is lower than the first power level and is sufficient to maintain the non-latching solenoid valve in the open position.
